(19) United States
(12) Patent Application Publication
(10) Pub. No.: US 2013/0133942 A1
(43) Pub. Date: May 30, 2013

(54) PROCESS FOR THE FABRICATION OF HIGHLY ELECTRICALLY-CONDUCTIVE POLYMER FOAMS WITH CONTROLLED COMPRESSION SET SUITABLE FOR USE IN EMI SHIELDING APPLICATIONS

(71) Applicants: Shalini Kandoor, Bangalore (IN); Bambore Lokeshwarappa Santhosh Kumar, Chitradurga (IN); Sreejith Valiavalappil, Kannur (IN); Bukkinakere Kapanipathaiya Chandrasekhar, Bangalore (IN)

(72) Inventors: Shalini Kandoor, Bangalore (IN); Bambore Lokeshwarappa Santhosh Kumar, Chitradurga (IN); Sreejith Valiavalappil, Kannur (IN); Bukkinakere Kapanipathaiya Chandrasekhar, Bangalore (IN)

(73) Assignee: Laird Technologies, Inc., Earth City, MO (US)

(21) Appl. No.: 13/750,138

(22) Filed: Jan. 25, 2013

Related U.S. Application Data
(63) Continuation-in-part of application No. PCT/US2011/045243, filed on Jul. 25, 2011.

(30) Foreign Application Priority Data
Jul. 26, 2010 (IN) 2125CHE2010

(51) Int. Cl. H05K 9/00

(52) U.S. Cl. CPC H05K 9/0088
USPC 174/388; 427/123; 156/185

(57) ABSTRACT

Disclosed herein are example embodiments of electromagnetic interference (EMI) shields and method of making EMI shields. In an exemplary embodiment, a method generally includes coating at least part of a core member with metallic material, and coating at least part of the metallic material with a polymer to thereby inhibit separation of the metallic material from the core member. An example EMI shield generally includes a core member, a metallic coating covering at least part of the core member, and a polymeric coating covering at least part of the metallic coating to inhibit separation of the metallic coating from the core member.

### CROSS-REFERENCE TO RELATED APPLICATIONS

This application is a continuation-in-part of PCT International Application No. PCT/US2011/045243 filed Jul. 25, 2011 (published as WO 2012/018595 on Feb. 9, 2012), which in turn claims priority to India Patent Application No. 2125/CHE/2010 filed Jul. 26, 2010. The entire disclosures of the above applications are incorporated herein by reference.

### FIELD

The present disclosure generally relates to electromagnetic interference (EMI) shielding and related methods. In particular, the present disclosure relates to EMI shielding and methods of making EMI shields, which may include foam/core members at least partly covered with metallic coatings and polymeric coatings wherein the polymeric coatings operate to help inhibit separation of the metallic coatings from the foam/core members during use of the EMI shields as well as provide superior compression set values.

### BACKGROUND

This section provides background information related to the present disclosure which is not necessarily prior art.

The operation of electronic devices generates electromagnetic radiation within the electronic circuitry of the equipment. Such radiation results in electromagnetic interference (EMI) or radio frequency interference (RFI), which can interfere with the operation of other electronic devices within a certain proximity. Without adequate shielding, EMI/RFI may cause degradation or complete loss of important signals, thereby rendering the electronic equipment inefficient or inoperable. A common solution to ameliorate the effects of EMI/RFI is through the use of shields capable of absorbing and/or reflecting EMI energy. These shields are typically employed to localize EMI/RFI within its source, and to insulate other devices proximal to the EMI/RFI source.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to an enclosure in which electronic equipment is disposed.

### SUMMARY

This section provides a general summary of the disclosure, and is not a comprehensive disclosure of its full scope or all of its features.

Disclosed herein are example embodiments of electromagnetic interference (EMI) shields and method of making EMI shields. In an exemplary embodiment, a method generally includes coating at least part of a core member with metallic material, and coating at least part of the metallic material with a polymer to thereby inhibit separation of the metallic material from the core member. An example EMI shield generally includes a core member, a metallic coating covering at least part of the core member, and a polymeric coating covering at least part of the metallic coating to inhibit separation of the metallic coating from the core member.

Another exemplary embodiment provides a method for making electrically conductive foam. In this example, the method generally includes cleaning a foam with a surfactant and etching the cleaned foam with dilute acid. The method may also include activating the etched foam by treatment with tin(II) chloride, palladium chloride/palladium acetate and silver nitrate or combinations thereof. The method may further include coating at least part of the activated foam with metallic material and coating at least part of the metallic material with a polymer to thereby inhibit separation of the metallic material from the foam. The resulting electrically-conducive foam may be used for EMI shielding applications or other applications.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a flow chart illustrating the various steps of an exemplary method for making an electromagnetic interference (EMI) shield comprising a foam/core member, metallic coating, and polymeric coating according to one or more aspects of the present disclosure;

FIG. 2 is a photograph of an exemplary polyurethane foam coated with metals and ethylene-propylene diene monomer (EPDM) according to one or more aspects of the present disclosure;

FIG. 3 is a scanning electron microscope (SEM) micrograph of a portion of the coated foam of FIG. 2 shown magnified 50× and illustrating the walls of the foam uniformly coated with metals and EPDM, according to one or more aspects of the present disclosure; and

FIG. 4 is a SEM micrograph of a portion of the coated foam of FIG. 2 shown magnified 100× and illustrating a single pore and exemplary manner in which the metallic particles are held intact by the EPDM coating, according to one or more aspects of the present disclosure.

Corresponding reference numerals indicate corresponding parts throughout the several views of the drawings.

### DETAILED DESCRIPTION

Example embodiments will now be described more fully with reference to the accompanying drawings.

According to various aspects, the inventors hereof have disclosed example embodiments of electromagnetic interference (EMI) shields which may include, for example, EMI shielding gaskets, input/output gaskets, profile gaskets, electrically-conductive foam, fabric-over-foam gaskets, other shielding devices, etc. The EMI shields may be used in a wide range of applications, installations, and electronic equipment such as, for example, computer servers, desktop computers, digital cameras, internal and external hard drives, liquid crystal displays, medical equipment, notebook computers, plasma display panels, printers, set top boxes, telecommunications enclosure cabinets, other electronic devices, other related devices, etc. The EMI shields can be used in electronic equipment, for example, to help inhibit leakage of EMI emissions through joints, gaps, openings, etc. in structural components (e.g., doors, walls, etc.) of the electronic equipment.

In some example embodiments, the EMI shields generally include a one-piece design comprising a core member (e.g., a foam core member, etc.) at least partly covered with a metallic coating and a polymeric coating. The metallic coating includes one or more layers of metallic particles covering at least part of the surface of the core member and provides electrical conductivity (or reducing resistivity) to the core member (and the EMI shield). And, the polymeric coating defines a layer covering at least part of the metallic coating and helps inhibit separation (e.g., falling off of metallic particles, etc.) from the core member during use (e.g., during flexing cycles, during compressing cycles, etc.) of the EMI shield. The polymeric coating may also cover or coat at least a part of the core member in some embodiments. In use, the polymeric coating helps maintain the integrity (e.g., helps inhibit deterioration, etc.) of the metallic coating and hence the electrical conductivity of the EMI shield. In alternative embodiments, the EMI shield may include an outer electrically-conductive fabric layer (e.g., nylon ripstock (NRS) fabric coated with nickel and/or copper, nickel-plated polyester or taffeta fabric, nickel/copper plated knit mesh, etc.), such that the EMI shield comprises a fabric-over-foam gasket. In such alternative embodiments, the fabric may be wrapped about the core member after the coating steps, and then bonded to the coated core member for example with a pressure sensitive adhesive, etc.

In some example embodiments, the core member may be formed from foam such as, for example, cellular polymeric foam (e.g., open-celled foam, partially open-celled foam, closed-cell foam, etc.). And, the foam may include a polyurethane foam (e.g., a polyester foam, a polyether foam, etc.), a polyvinyl chloride foam, an ethylene vinyl acetate foam, polypropylene foam, poly vinyl chloride foam, polystyrene foam, polymethacrylimide foam, polyethylene foam, EPDM foam, neoprene foam, rubber foam, etc. The foam core member of these example embodiments may have any desired shape and/or dimensions (e.g., foam thickness of 0.3 millimeter or above, etc.), for example, depending on uses of the EMI shields containing the core member. In addition, the foam core member may include flame retardant material incorporated therein, applied thereto, etc. as desired. By way of example, the open cell foams can have pores corresponding to typically 30 pores per linear inch to 80 pores per linear inch.

In some example embodiments, the metallic coating may include one or more layers (e.g., one layer, multiple layers, etc.) of metallic particles applied to the core member by a suitable process (e.g., via electroless plating, dip coating using polymeric binders, arc spraying, in-situ metallization, etc.). For example, the metallic coating may include a first layer of metallic particles covering substantially all of the surface of the core member, and a second layer of metallic particles (e.g., the same metallic particles as used in the first layer, different metallic particles than used in the first layer, etc.) covering substantially all of the first layer of metallic particles. The metallic particles used to form the layers of the metallic coating may include, but are not limited to, palladium, platinum, gold, aluminum, silver, copper, nickel, tin, alloys thereof, etc. In other example embodiments, the metallic coating may cover less than substantially all of the surface of the core member, or the metallic coating may entirely cover the surface of the core member.

In some example embodiments, the metallic particles may be applied to the core member in one or more layers (defining the metallic coating) such that the one or more layers each have a desired (e.g., predetermined, etc.) thickness (e.g., a desired plating weight, etc.). The metallic coating may thus have a desired thickness (e.g., less than about 1 micrometers, about 0.3 micrometers, about 0.1 micrometer or more, etc.). Moreover, the thickness of these metallic layers may be associated with desired (e.g., predetermined, etc.) electrical conductivities (or resistivities) of the EMI shields (e.g., surface resistivities (e.g., along X-Y axes, etc.) of about 1 ohms per square or less and/or Z-axis resistivities of about 1 ohm-centimeter or less, etc.). As such, the thicknesses of the metallic coatings (and the metallic layers making up the metallic coatings) can be controlled/adjusted to thereby control/adjust electrical conductivities of the EMI shields. For example, EMI shields may be prepared with metallic coatings having desired numbers of metallic layers, formed from desired metals, and having desired thicknesses so that the resulting EMI shields exhibit desired (and substantially predetermined) electrical conductivities.

In some example embodiments, the polymeric coating may be formed from an ethylene propylene copolymer such as, for example, an ethylene-propylene monomer (EPM), an ethylene-propylene diene monomer (EPDM), combinations thereof, etc. In some of these example embodiments, the polymeric coating may cover substantially all of the metallic coating. In other ones of these example embodiments, the polymeric coating may cover less than substantially all of the metallic coating, or the polymeric coating may entirely cover the metallic coating. The polymeric coating may also directly cover, coat, or contact at least a part of the core member in some embodiments. The polymeric coating may comprise one or more of EPM, EPDM, urethane, vinyl, nitrile rubber, acrylic, and/or siloxane in various exemplary embodiments.

Example embodiments of the EMI shields of the present disclosure may exhibit good electrical conductivity (and resistivity). For example, some example embodiments of the EMI shields may exhibit surface resistivities (e.g., along X-Y axes, etc.) of about 0.1 ohms per square or less and/or Z-axis resistivities of about 0.03 ohms-centimeter or less. Example embodiments of the EMI shields may also provide high degrees of shielding effectiveness, for example, greater than about 50 decibels (from about 100 kilohertz to about 5 gigahertz). Example embodiments of the EMI shields may further exhibit low compression sets, for example, about 20 percent or less (e.g., about 10 percent or less, etc.). Moreover, example embodiments of the EMI shields may have service temperatures up to at least about 85 degrees Celsius. As such, example embodiments of the EMI shields may provide effective electrical conductivity necessary for EMI shielding along with very low closure forces in a single component product.

In addition, exemplary embodiments also provide methods for making electrically conductive foam. In one such exemplary embodiment, a method generally includes cleaning a foam with a surfactant and etching the cleaned foam with dilute acid. The method may also include activating the etched foam by treatment with tin(II) chloride, palladium chloride/palladium acetate and silver nitrate or combinations thereof. The method may further include coating at least part of the activated foam with metallic material and coating at least part of the metallic material with a polymer to thereby inhibit separation of the metallic material from the foam. The resulting electrically-conducive foam may be used for EMI shielding applications. But the electrically-conductive foam made according to this method (as can the other electrically-conductive foams disclosed herein) may also be used in other applications besides EMI shielding.

Example embodiments will now be described more fully with reference to the accompanying drawings.

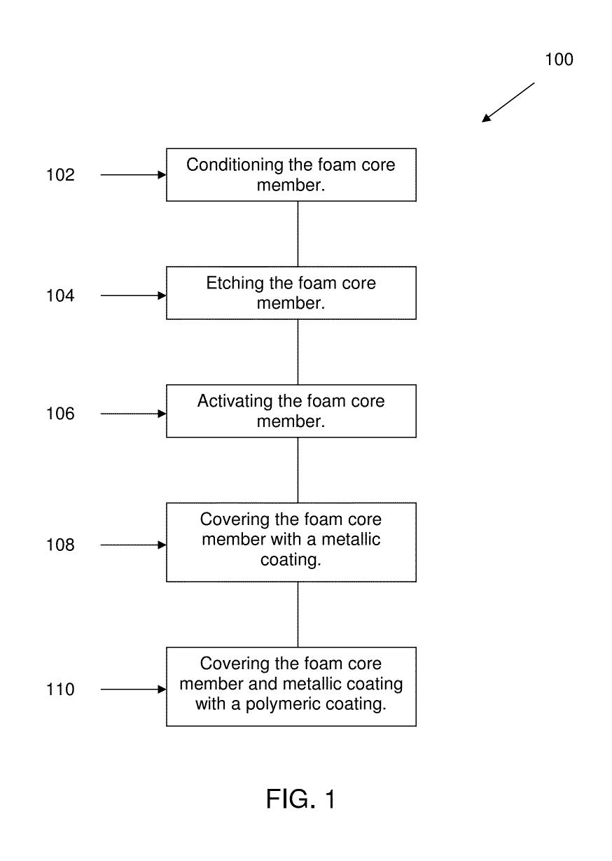

FIG. 1 illustrates an example method 100 for making an EMI shield including one or more aspects of the present disclosure. In this example embodiment, the EMI shield formed in accordance with the method 100 generally includes a foam core member. As such, the illustrated method 100 generally includes various pretreatment operations (e.g., operations 102, 104, 106, etc.) for preparing the surface of the foam to receive a metallic coating of copper and nickel particles (while inhibiting subsequent peeling of the metallic coating from the foam). The method then includes operations (e.g., operation 108, etc.) for applying the metallic coating over the surface of the foam core member (to make the foam electrically conductive), and operations (e.g., operation 110, etc.) for applying an ethylene propylene copolymer (such as, for example, an ethylene-propylene monomer (EPM), an ethylene-propylene diene monomer (EPDM), etc.), coating over the metallic coating (to inhibit the copper and nickel particles from separating from the foam core member during use of the EMI shield). This coating of EPM/EPDM also facilitates improved compression set of the coated foam.

As shown in FIG. 1, the illustrated method 100 includes an operation 102 of conditioning (e.g., cleaning, etc.) the foam core member in preparation for covering the surface of the foam core member with the metallic coating and the ethylene propylene copolymer coating. The conditioning operation 102 generally includes cleaning the foam core member with a cleaning solution and then rinsing the cleaned foam core member with water. The cleaning solution is configured to remove contaminates (e.g., dirt, debris, grease etc.) from the foam core member, but may also operate to impart an electrical charge to the foam core member (e.g., a negative charge, etc.) that facilitates receipt of metallic particles of the metallic coating on the surface of the foam core member. The rinsing water is configured to remove any residual cleaning solution from the foam core member following application of the cleaning solution. Cleaning and rinsing the foam core member, as part of the conditioning operation 102, may include applying the cleaning solution and/or the rinsing water to the foam core member via any suitable process including, for example, a continuous stream, a spray, a bath (soaking the core member within a volume of the cleaning solution), combinations thereof, etc. such that substantially all of the surfaces (e.g., exposed outer surfaces, etc.) of the foam core member are contacted by the cleaning solution and/or the rinsing water.

As an example, cleaning solution suitable for use in the conditioning operation 102 may include a water-based surfactant solution. The surfactant may include any suitable surfactant, for example, an anionic surfactant, a cationic surfactant, a nonionic surfactant, a combination thereof, etc. And, the surfactant may be present in the cleaning solution at a concentration between, for example, about 0.1 percent by volume and about 8 percent by volume, etc. The cleaning solution may be applied to the core member at a temperature between, for example, about 15 degrees Celsius and about 85 degrees Celsius, etc. for a desired length of time (e.g., between about 3 minutes and about 30 minutes, etc.).

The rinsing water used to remove residual cleaning solution from the foam core member may include, for example, deionized water, distilled water, tap water, etc. within the scope of the present disclosure. The rinsing water may be applied to the cleaned foam core member at a temperature between, for example, about 10 degrees Celsius and about 50 degrees Celsius, etc. for a desired length of time (e.g., between about 1 minute and about 30 minutes, etc.).

The illustrated method 100 also includes an operation 104 of etching the foam core member with an acid solution to roughen (e.g., score, etc.) the surface of the foam core member and to facilitate generally even deposition and adhesion of the metallic layer on the surface of the foam core member. The acid solution may include any suitable acid solution within the scope of the present disclosure including, for example, a hydrochloric acid (HCl) solution, a sulfuric acid (H2SO4) solution, combinations thereof, etc. Any suitable concentration of acid solution may be used including, for example, an acid solution having a concentration of between about 2 percent by volume and about 35 percent by volume, etc. The acid solution may be applied to the foam core member at a temperature between, for example, about 10 degrees Celsius and about 60 degrees Celsius, etc. for a desired length of time (e.g., between about 2 minutes and about 60 minutes, etc.). In addition, the acid solution may be applied to the foam core member via any suitable process including, for example, a continuous stream, a spray, a bath, combinations thereof, etc. such that substantially all of the surfaces of the foam core member are contacted by the acid solution. The foam core member may then be rinsed with water, as desired, to help remove any residual acid solution from the foam core member following the etching operation 104.

In other example embodiments, methods may include operations of etching core members with alkaline solutions such as, for example, sodium hydroxide (NaOH) solutions, potassium hydroxide (KOH) solutions, combinations thereof, etc. having concentrations between about 0.25 percent by volume and about 40 percent by volume, etc. In these example embodiments, the alkaline solutions may be applied to the core members at temperatures between about 10 degrees Celsius and about 100 degrees Celsius for desired lengths of time (e.g., between about 1 minute and about 60 minutes, etc.).

The illustrated method 100 may also include a neutralizing operation that includes applying a neutralizing solution to the foam core member following the etching operation 104. The neutralizing solution helps neutralize any acidic (or alkaline) solution remaining on the foam core member from the etching operation 104. Any suitable neutralizing solution may be used within the scope of the present disclosure including, for example, sodium hydroxide (NaOH) solution, potassium hydroxide (KOH) solution, combinations thereof, etc. when an acid etching operation is used (or, alternatively, a hydrochloric (HCl) solution, a sulfuric acid (H2SO4) solution, etc. when an alkaline etching operation is used). And, any suitable concentration of neutralizing solution may be used, for example, a neutralizing solution having an acidic (or alkaline) concentration between about 2 percent by volume and about 28 percent by volume. In addition, the neutralizing solution may be applied to the foam core member at a temperature between, for example, about 10 degrees Celsius and about 60 degrees Celsius, etc. for a desired length of time (e.g., between about 1 minute and about 30 minutes, etc.) via any suitable process (e.g., a continuous stream, a spray, a bath, combinations thereof, etc.) such that substantially all of the surfaces of the foam core member are contacted by the neutralizing solution. The foam core member may then be rinsed with water, as desired, to help remove any residual neutralizing solution from the foam core member following the neutralizing operation.

With continued reference to FIG. 1, the illustrated method 100 also includes an operation 106 of activating the foam core member for receiving the metallic coating. This operation 106 includes applying both a sensitizing solution and an activating solution to the foam core member (separately or in combination). The sensitizing solution prepares the foam core member for contact with the activating solution. For example, the sensitizing solution may include a material that bonds with the foam core member and then facilitates subsequent adhering of the activating solution thereto. The activating solution then establishes catalytic sites on the surface of the foam core member (e.g., via operation of the sensitizing solution, etc.) that help retain the metallic particles of the metallic coating on the foam core member.

An example sensitizing solution suitable for use in the activating operation 106 may include a solution of salt, solvent, and water. The salt (which bonds with the core member) may include, for example, stannous chloride (SnCl2), stannic chloride (SnCl4) combinations thereof, etc. And, the solvent may include, for example, an alcohol such as ethanol, an acid such as hydrochloric (HCl) acid, combinations thereof, etc. The salt may be present in the sensitizing solution at a volumetric concentration between, for example, about 8 grams per liter and about 250 grams per liter; and the solvent may be present in the sensitizing solution at a concentration between, for example, about 2 percent by volume and about 30 percent by volume. The sensitizing solution may be applied to the foam core member at a temperature between, for example, about 10 degrees Celsius and about 45 degrees Celsius, etc. for a desired length of time (e.g., between about 3 minutes and about 45 minutes, etc.). In addition, the sensitizing solution may be applied to the foam core member via any suitable process including, for example, a continuous stream, a spray, a bath, combinations thereof, etc. such that substantially all of the surfaces of the foam core member are contacted by the sensitizing solution.

An example activating solution suitable for use in the activating operation 106 may include a solution of metal, solvent, and water (where the metal is dissolved in the solvent). The metal may include any suitable metal (e.g., gold, silver, palladium, platinum, combinations thereof, etc.) or metal compound (e.g., gold chloride (AuCl2), silver nitrate (AgNO3), palladium chloride (PdCl2), platinum chloride (PtCl2), combinations thereof, etc.). And, the solvent may include, for example, an acid solution such as an acetic acid (CH3COOH), a hydrochloric (HCl) solution, a sulfuric acid (H2SO4) solution, combinations thereof, etc. The solvent (and dissolved metal) may be present in the activating solution at a concentration between, for example, about 5 percent and about 70 percent by volume. Addition of reagents like ammonium hydroxide can also facilitate the reduction of silver nitrate The activating solution may be applied to the foam core member at a temperature between, for example, about 10 degrees Celsius and about 75 degrees Celsius, etc. for a desired length of time (e.g., between about 1 minute and about 60 minutes, etc.) via any suitable process (e.g., a continuous stream, a spray, a bath, combinations thereof, etc.) such that substantially all of the surfaces of the foam core member are contacted by the activating solution.

The example method 100 also includes an operation 108 of covering (e.g., via electroless plating, dip coating using polymeric binders, arc spraying, in-situ metallization coating, etc.) the activated foam core member with a metallic coating having a thickness of at least about 0.1 micrometer or more. In the illustrated method 100, this metalizing operation 108 includes plating (e.g., electroless plating, etc.) the foam core member with copper and nickel particles to form the metallic coating. For example, the metalizing operation 108 includes plating the foam core member with a first layer of copper, and then plating the first layer of copper with a second layer of nickel. As part of this metalizing operation 108, the foam core member may be subjected to an additional activating operation (e.g., activating operation 106, etc.) after the foam core member is plated with the first layer of copper and before the foam core member is plated with the second layer of nickel. Thus, the foam core member (as part of the illustrated method 100 and the metalizing operation 108) is subjected to two activating operations and two plating operations. Following the metalizing operation 108, the surface of the plated foam core member may be further treated with a corrosion resistant agent to help improve corrosion resistance of the metallic coating. In other example embodiments, foam core members may be subjected to multiple activating operations and multiple plating operations to prepare and cover the foam core member with multiple layers of the same (or different) metallic particles.

With continued reference to FIG. 1, the example method also includes an operation 110 of covering (e.g., coating, etc.) the metallic coating on the foam core member with the ethylene propylene copolymer (such as, for example, an ethylene-propylene monomer (EPM), an ethylene-propylene diene monomer (EPDM), etc.), coating. In so doing, the ethylene propylene copolymer coating defines a layer over the metallic coating (and generally over the foam core member) that operates to inhibit separation of (e.g., falling off of, etc.) the metallic coating (e.g., the metallic particles thereof, etc.) from the core member during use (e.g., during flexing cycles, during compressing cycles, etc.) of the EMI shield. For the coating procedure of EPM/EPDM, 1 to 10 weight percent of EPM/EPDM is dissolved in 90 to 99 volume percent of a solvent such as Toluene, Tetrahydro furan, Dicholro methane, etc. The ethylene propylene copolymer solution may be applied to the foam core member at a temperature between, for example, about 10 degrees Celsius and about 75 degrees Celsius, etc. for a desired length of time (e.g., between about 1 minute and about 60 minutes, etc.) via any suitable process (e.g., a continuous stream, a spray, a bath, combinations thereof, etc.) such that substantially all of the surfaces of the metal coated foam core member are contacted by the polymeric solution

It is noted that any of the above-described operations (e.g., operations 102, 104, 106, 108, 110, etc.) may be performed as a batch process, a continuous process, a combination thereof, etc. In addition, each of the operations can be performed in any suitable sequence and/or simultaneously as desired. Further, the method 100 may include fewer or additional operations to those described. For example, one or more of the operations (or parts thereof) for preparing the surface of the foam core member to receive the metallic coating could be eliminated in certain cases, for example, when specific types of foams are used to form the core members (e.g., when a quenched polymeric foam is used for the core member for the EMI shield, etc.).

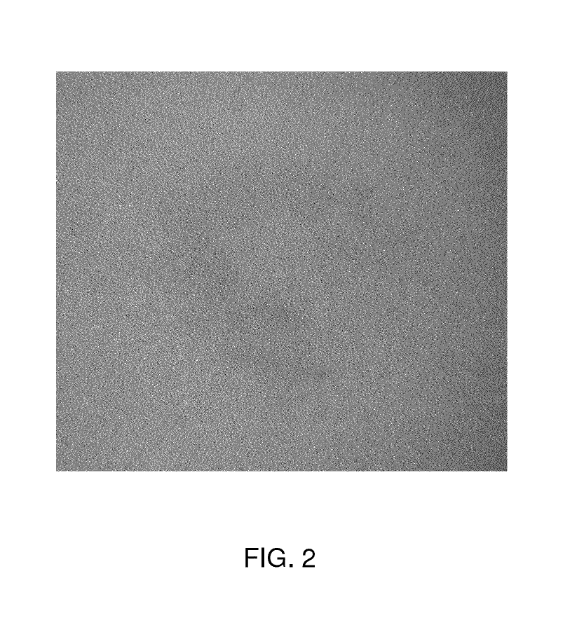

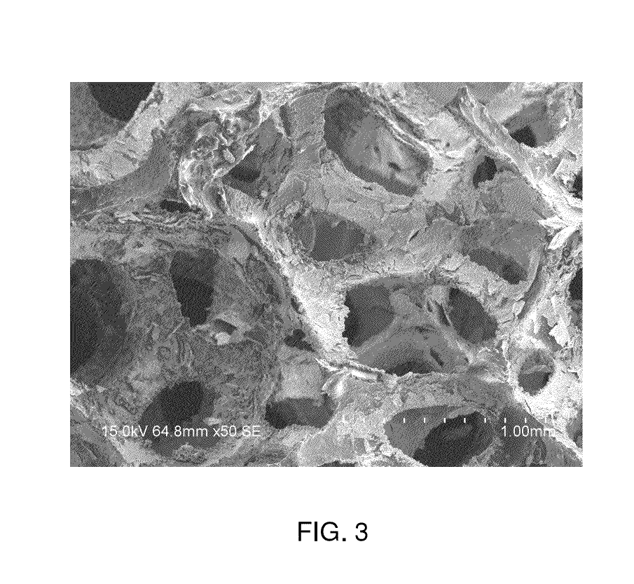

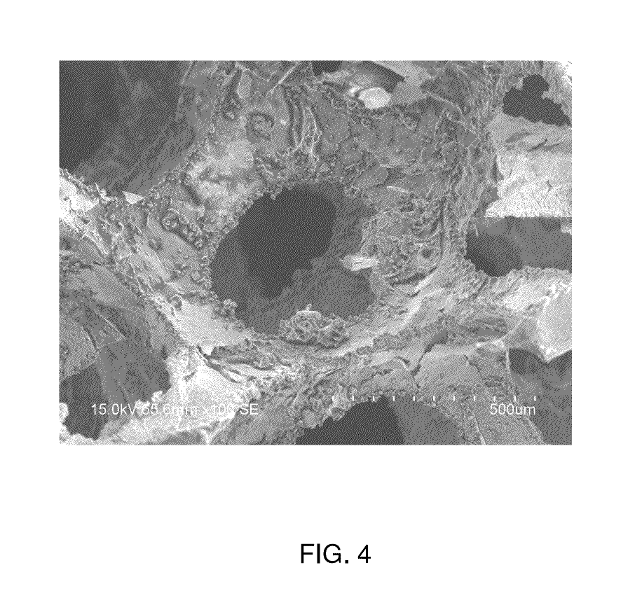

FIGS. 2 through 4 illustrate an example embodiment of an EMI shield made in accordance with the example method 100. The EMI shield generally includes a core member coated with metallic layers of copper and nickel, which are further coated with an ethylene-propylene diene monomer (EPDM) layer to inhibit separation of the copper and nickel layers from the core member. More specifically, FIG. 2 is a photograph of an exemplary polyurethane foam coated with metallic layers of copper and nickel and an EPDM. FIG. 3 is a scanning electron microscope (SEM) micrograph of a portion of the coated foam of FIG. 2 shown magnified 50× and illustrating the walls of the foam uniformly coated with metals and EPDM. FIG. 4 is a SEM micrograph of a portion of the coated foam of FIG. 2 shown magnified 100× and illustrating a single pore and exemplary manner in which the metallic particles are held intact by the EPDM coating.

Table 1 below provides typical X-Y electrical conductivity (surface resistance in ohms per square), Z electrical conductivity (Z-axis resistivity in ohms-centimeter), compression set (percentage at 70° C. for 22 hours) and shielding effectiveness (negative decibels) obtained for two samples having different thicknesses (5.08 millimeters and 5.33 millimeters) from the EMI shielding material shown in FIGS. 2 through 4.

TABLE 1

| | | Sample 1 | Sample 2 |
|---|---|---|---|
| Thickness(mm) | | 5.08 | 5.33 |
| Surface Resistance | 1 | 0.086 | 0.073 |
| (ohms per square) | 2 | 0.083 | 0.073 |
| | Avg. | 0.085 | 0.073 |
| Z-Axis Resistivity | 1 | 0.009 | 0.014 |
| (ohms-centimeter) | 2 | 0.012 | 0.011 |
| | 3 | 0.014 | 0.014 |
| | 4 | 0.017 | 0.014 |
| | 5 | 0.014 | 0.013 |
| | Avg. | 0.013 | 0.013 |
| Shielding | 500M Hz | −86.73 | −79.87 |
| Efficiency | 1 G Hz | −88.35 | −82.89 |
| (negative decibels (−dB)) | 2 G Hz | −88.05 | −87.18 |
| Compression set(%) | 1 | 10.86% | 11.85% |
| (at 70° C. for 22 hours) | 2 | 13.27% | 11.87% |
| | 3 | 13.46% | 11.81% |
| | 4 | 12.01% | 11.75% |
| | 5 | 11.09% | 11.38% |
| | 6 | 11.99% | 14.26% |
| | Avg. | 12.11% | 12.15% |

### EXAMPLES

By way of example only and not for purposes of limitation, a description will now be provided of exemplary methods for making, producing or forming electrically-conductive polyurethane foam.

### Example 1

In this first example, an electrically-conductive polyurethane foam may be formed by:

A. cleaning the polyurethane foam using a 2% aqueous surfactant solution at 25° C.;

B. surface treating with a 5 vol % (volume percent) hydrochloric acid (HCl) solution at 25° C. for 2 minutes;

C. sensitizing with 20 g/l (grams per liter) of stannous chloride (SnCl₂) solution and 35 vol % HCl solution at 25° C. for 45 minutes;

D. activating with a 20 g/l silver nitrate (AgNO₃) solution and 25 vol % of ammonia at 25° C. for 45 minutes;

E. electroless plating of copper using 15 g/l of copper sulfate, 39 ml of formaldehyde (37 to 41 weight/volume percent (w/v %)), 37 g/l of sodium potassium tartrate and 11 g/l of sodium hydroxide (NaOH) (pH ˜12 to 13) for 30 minutes at 30° C.;

F. electroless plating of nickel using 4 g/l of nickel chloride, 50 milliliters (ml) of ammonia (25 vol %), 2 g/l of ammonium sulfate, 10 g/l of sodium hypophosphite, and 60 ml of hydrazine for 30 minutes at 80° C. to 85° C.; and

G. ethylene propylene monomer (EPM) coating using 5 vol % solution in toluene at 30° C. for 2 minutes.

The foam is rinsed with water between steps.

### Example 2

In this second example, an electrically-conductive polyurethane foam may be formed by:

A. cleaning the polyurethane foam using a 2% aqueous surfactant solution at 25° C.;

B. surface treating with a 5 vol % hydrochloric acid (HCl) solution at 25° C. for 2 minutes;

C. sensitizing with 20 g/l of stannous chloride (SnCl₂) solution and 35 vol % HCl solution at 25° C. for 45 minutes;

D. activating with a 20 g/l silver nitrate (AgNO₃) solution and 25 vol % of ammonia at 25° C. for 45 minutes;

E. electroless plating of copper using 18 g/l of copper sulfate, 50 ml of formaldehyde (37 to 41 w/v %), 45 g/l of sodium potassium tartrate and 13 g/l of sodium hydroxide (NaOH) (pH ˜12 to 13) for 30 minutes at 30° C.;

F. electroless plating of nickel using 4 g/l of nickel chloride, 50 ml of ammonia (25 vol %), 2 g/l of ammonium sulfate, 10 g/l of sodium hypophosphite, and 60 ml of hydrazine for 30 min at 80° C. to 85° C.; and

G. ethylene propylene monomer (EPM) coating using 5 vol % solution in toluene at 30° C. for 2 minutes.

The foam is rinsed with water between steps.

Exemplary embodiments are disclosed of processes for the fabrication of highly electrically-conductive foams and EMI shields including such highly electrically-conductive foams. In an exemplary embodiment, an EMI shield includes a metal layer having a thickness of 100 nanometers or more, where the metal layer may be non-flat (e.g., uneven, curved, etc.). In this example, the EMI shield has a sheet resistivity, surface resistivity, and Z-axis resistivity of about 1 ohm-centimeter or less. Also in this example, the EMI shield does not require or have a polymer base coat layer between the foam core member and one or more metal layer(s), does not require or have adhesion enhancement treatment for metal and polymeric layers, and does not require or have in situ cross linking via in situ cross linked polymeric protective layer based on acrylates. In some exemplary embodiments in which the EMI shield includes more than one metal layer, the EMI shield does not require or have any polymeric layers in-between the metal layers separating the metal layers.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally,” “about,” and “substantially,” may be used herein to mean within manufacturing tolerances. Or for example, the term “about” as used herein when modifying a quantity of an ingredient or reactant of the invention or employed refers to variation in the numerical quantity that can happen through typical measuring and handling procedures used, for example, when making concentrates or solutions in the real world through inadvertent error in these procedures; through differences in the manufacture, source, or purity of the ingredients employed to make the compositions or carry out the methods; and the like. The term “about” also encompasses amounts that differ due to different equilibrium conditions for a composition resulting from a particular initial mixture. Whether or not modified by the term “about,” the claims include equivalents to the quantities.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for making an electromagnetic interference (EMI) shield, the method comprising:
coating at least part of a core member with metallic material; and
coating at least part of the metallic material with a polymer to thereby inhibit separation of the metallic material from the core member.

2. The method of claim 1, wherein coating at least part of the core member with metallic material includes electroless plating at least part of the core member with the metallic material.

3. The method of claim 1, wherein coating at least part of the core member with metallic material includes coating all of the core member with the metallic material.

4. The method of claim 1, wherein:
coating at least part of the core member with metallic material includes coating at least part of the core member with the metallic material to a thickness of about 0.1 micrometer or more; and/or
coating at least part of the core member with metallic material includes coating at least part of the core member with the metallic material in a predetermined thickness such that the EMI shield exhibits a desired electrical conductivity and EMI efficiency; and/or
coating at least part of the metallic material with the polymer includes coating all of the metallic material with a polymer.

5. The method of claim 1, wherein the core member includes a foam.

6. The method of claim 5, wherein the foam comprises at least one of polyurethane foam, polyester foam, polyether foam, polyvinyl chloride foam, ethylene vinyl acetate foam, polypropylene foam, poly vinyl chloride foam, polystyrene foam, polymethacrylimide foam, polyethylene foam, EPDM foam, neoprene foam, and/or rubber foam.

7. The method of claim 1, wherein:
the core member comprises at least one of polyurethane, polyester, polyether, polyvinyl chloride, ethylene vinyl acetate, polypropylene, poly vinyl chloride, polystyrene, polymethacrylimide, polyethylene, EPDM, neoprene, and/or rubber; and/or the core member has a thickness of about 0.3 millimeter or higher;
and/or the metallic material includes at least one of copper, gold, aluminum, silver, tin, and nickel; and/or
the polymer includes at least one of an ethylene propylene monomer (EPM) an ethylene-propylene diene monomer (EPDM), urethane, vinyl, nitrile rubber, and siloxane.

8. The method of claim 1, wherein the EMI shield:
has a surface resistivity of about 1 ohms per square or less; and/or
has a Z-axis resistivity of about 1 ohm-centimeter or less; and/or
has a shielding effectiveness of about 50 decibels or more; and/or
is configured for operation at service temperatures up to about 85 degrees Celsius; and/or
has a compression set of about 20 percent or less.

9. The method of claim 1, wherein the metallic material includes copper and nickel, and wherein the method further comprises, prior to coating at least part of the core member with copper and nickel:
cleaning the core member with a surfactant;
etching the cleaned core member with dilute acid; and
activating the etched core member by treatment with tin(II) chloride, palladium chloride/palladium acetate and silver nitrate or combinations thereof.

10. The method of claim 1, wherein at least part of the core member is coated with polymer.

11. The method of claim 1, further comprising wrapping an electrically-conductive fabric material about at least a portion of the core member after the coating steps, to thereby provide a fabric-over-foam gasket.

12. An EMI shield made according to the method of claim 1.

13. An electromagnetic interference (EMI) shield comprising:
a core member;
a metallic coating covering at least part of the core member; and
a polymeric coating covering at least part of the metallic coating to inhibit separation of the metallic coating from the core member.

14. The EMI shield of claim 13, wherein:
the metallic coating covers all of the core member; and/or
the metallic coating has a thickness of about 0.1 micrometer or more; and/or
the metallic coating has a predetermined thickness corresponding to a desired electrical conductivity for the EMI shield; and/or
the polymer coating covers all of the metallic coating; and/or
at least part of the core member is coated with polymer.

15. The EMI shield of claim 13, wherein the core member includes a foam.

16. The EMI shield of claim 15, wherein the core member comprises at least one of polyurethane foam, polyester foam, polyether foam, polyvinyl chloride foam, ethylene vinyl acetate foam, polypropylene foam, poly vinyl chloride foam, polystyrene foam, polymethacrylimide foam, polyethylene foam, EPDM foam, neoprene foam, and/or rubber foam.

17. The EMI shield of claim 13, wherein the core member comprises at least one of polyurethane, polyester, polyether, polyvinyl chloride, ethylene vinyl acetate, polypropylene, poly vinyl chloride, polystyrene, polymethacrylimide, polyethylene, EPDM, neoprene, and/or rubber.

18. The EMI shield of claim 13, wherein:
the metallic coating is formed from at least one of copper, gold, aluminum, silver, tin, and nickel; and/or
the polymer coating is formed from at least one of an ethylene propylene monomer (EPM) and an ethylene-propylene diene monomer (EPDM), urethane, vinyl, nitrile rubber, and/or siloxane; and/or
the metallic coating includes at least one layer of copper particles and/or at least one layer of nickel particles.

19. The EMI shield of claim 13, wherein the EMI shield:
has a surface resistivity of about 1 ohms per square or less; and/or
has a Z-axis resistivity of about 1 ohm-centimeter or less; and/or
has a shielding effectiveness of about 50 decibels or more; and/or
is configured for operation at service temperatures up to about 85 degrees Celsius; and/or
has a compression set of about 20 percent or less.

20. The EMI shield of claim 13, further comprising an outer electrically-conductive fabric layer.

21. An electromagnetic interference (EMI) shield comprising:
a foam core member coated with activator such as silver or palladium;
a metallic coating comprising copper and nickel and covering at least part of the foam core member; and
a polymeric coating comprising an ethylene propylene copolymer and covering at least part of the metallic coating to inhibit separation of the metallic coating from the foam core member;
wherein the metallic coating has a thickness of about 0.1 micrometer or more;
wherein the EMI shield has a surface resistivity of about 1 ohms per square or less and/or a Z-axis resistivity of about 1 ohm-centimeter or less; and
wherein the EMI shield has a compression set of about 20 percent or less.

22. A method for making electrically conductive foam, the method comprising:
cleaning a foam with a surfactant;
etching the cleaned foam with dilute acid; and
activating the etched foam by treatment with tin(II) chloride, palladium chloride/palladium acetate and silver nitrate or combinations thereof;
coating at least part of the activated foam with metallic material; and
coating at least part of the metallic material with a polymer to thereby inhibit separation of the metallic material from the foam.

23. The method of claim 22, wherein:
the foam comprises at least one of polyurethane foam, polyester foam, polyether foam, polyvinyl chloride foam, ethylene vinyl acetate foam, polypropylene foam, poly vinyl chloride foam, polystyrene foam, polymethacrylimide foam, polyethylene foam, EPDM foam, neoprene foam, and/or rubber foam; and
the polymer comprises at least one of an ethylene propylene monomer (EPM) an ethylene-propylene diene monomer (EPDM), urethane, vinyl, nitrile rubber, and siloxane; and
the metallic material includes at least one of copper, gold, aluminum, silver, tin, and nickel.
